(19) United States
(12) Patent Application Publication
(10) Pub. No.: US 2024/0018673 A1
(43) Pub. Date: Jan. 18, 2024

(54) ELECTROCATALYST HAVING QUASI-TWO-DIMENSIONAL METAL NANOSHEET HAVING TURING STRUCTURE MORPHOLOGY

(71) Applicant: City University of Hong Kong, Hong Kong (HK)

(72) Inventors: Jian LU, Hong Kong (HK); Jialun GU, Hong Kong (HK); Lanxi LI, Hong Kong (HK)

(21) Appl. No.: 17/864,395

(22) Filed: Jul. 14, 2022

(51) Int. Cl. C25B 11/081; C23C 14/18; C23C 14/58; C25B 1/04

(52) U.S. Cl. CPC C25B 11/081; C23C 14/185; C23C 14/5873; C23C 14/584; C25B 1/04

(57) ABSTRACT

The invention discloses an electrocatalyst includes a quasi-two-dimensional metal nanosheet having a thickness ranging between 4 nm and 12 nm. The quasi-two-dimensional metal nanosheet includes platinum (Pt), nickel (Ni), and niobium (Nb). The quasi-two-dimensional metal nanosheet has a Turing structure morphology including one or more of Turing stripes and Turing spots assembled by individual metal nanocrystals having different orientations via constrained orientation attachment.

### COPYRIGHT NOTICE

A portion of the disclosure of this patent document contains material, which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF THE INVENTION

The invention relates to the technical field of electrocatalyst. In particular, it relates to electrocatalyst having platinum for energy conversion.

### BACKGROUND OF THE INVENTION

Highly active and durable electrocatalyst is the basis for large-scale application of hydrogen related renewable energy. One efficient approach for higher activity is to reduce material dimension to low-dimensional nano-scale, for example, nanosheet, nanowire and nanoparticle, for high surface-to-volume ratio. The mechanism behind activity improvement is the optimization of active sites and electronic structures by ligand effects and strain-engineering. Nevertheless, poor intrinsic stability is often seen on nanoscale electrocatalyst. Sub-nanoscale structure is thermodynamically unfavorable. The decrease in system energy drives the nanoscale structure to reconstruct by decomposing highly active sites. This reconstruction leads to agglomeration to bulky particles, and hence a sharp decline in catalytic-stability. For example, the mass activity of nano-Pt/C, as a benchmark electrocatalyst, decreases by 50% in accelerated stability tests, and the particle diameter increases from 3 nm to 8 to 27 nm due to the Ostwald ripening effects. Stability of highly active electrocatalysts has presented a difficult issue in the electrocatalyst for energy conversion.

### SUMMARY OF THE INVENTION

This section is for the purpose of summarizing some aspects of embodiments of the invention and to briefly introduce some further embodiments. In this section, as well as in the abstract and the title of the invention of this application, simplifications or omissions may be made to avoid obscuring the purpose of the section, the abstract and the title, and such simplifications or omissions are not intended to limit the scope of the invention.

The present invention has been made in view of the above-mentioned problems of a stable low-dimensional nanoscale electrocatalyst.

Accordingly, one aspect of the present invention provides an electrocatalyst includes a quasi-two-dimensional metal nanosheet having a thickness ranging between 4 nm and 12 nm. The quasi-two-dimensional metal nanosheet includes platinum (Pt), nickel (Ni), and niobium (Nb). The quasi-two-dimensional metal nanosheet has a Turing structure morphology including one or more of Turing stripes and Turing spots assembled by individual metal nanocrystals having different orientations via constrained orientation attachment.

In a further embodiment of the present invention, the Pt is in a range between 10 and 75%, Ni is in a range between 20 and 60%, and Nb is in a range between 5 and 30%.

In a further embodiment of the present invention, the quasi-two-dimensional metal nanosheet has a face-centered cubic (fcc) structure.

In a further embodiment of the present invention, the Turing structure morphology includes five-fold twins enclosed by {111} and {200} atomic planes.

In a further embodiment of the present invention, a lattice strain of the quasi-two-dimensional metal nanosheet is in a range between 2.5 and 4.3%.

In a further embodiment of the present invention, the Turing stripes are rotational crystals.

Another aspect of the present invention provides a method of manufacturing the quasi-two-dimensional metal nanosheet catalyst includes forming a buffer layer by sputtering. A metal layer is formed over the buffer layer by sputtering. The metal layer has platinum, nickel, and niobium. The buffer layer and the metal layer are exfoliated in an alkaline solution. An ultrasonic treatment is performed to the buffer layer and the metal layer for at least one cycle.

In a further embodiment of the present invention, the forming the buffer layer by sputtering and forming the metal layer over the buffer layer is magnetron sputtering.

In a further embodiment of the present invention, the buffer layer is selected from the group consisting of SiO₂, ZnO₂, Cr₂O₃, tin (Sn), aluminum (Al), and lead (Pb).

In a further embodiment of the present invention, the Pt is in a range between 10 and 75%, Ni is in a range between 20 and 60%, and Nb is in a range between 5 and 30%.

In a further embodiment of the present invention, the exfoliating the buffer layer and the metal layer in the alkaline solution is performed at a temperature ranging between 310 and 370K.

In a further embodiment of the present invention, the performing ultrasonic treatment to the buffer layer and the metal layer for at least one cycle is conducted at a temperature ranging between 270 and 300K.

In a further embodiment of the present invention, the performing ultrasonic treatment to the buffer layer and the metal layer has two cycles, and each cycle has a different temperature.

### BRIEF DESCRIPTION OF THE DRAWINGS

In order to more clearly illustrate the technical solutions of the embodiments of the present invention, the drawings needed to be used in the description of the embodiments will be briefly introduced below. It is noted that the drawings in the following description are only some embodiments of the present invention, and it is noted for those skilled in the art to obtain other drawings based on these drawings without inventive exercise, in which:

FIGS. 1A to 1D show a schematic diagram of a method of manufacturing a quasi-two-dimensional metal nanosheet according to an embodiment of the present invention;

FIG. 2 is a low magnification TEM image of a quasi-two-dimensional metal nanosheet according to an embodiment of the present invention;

FIGS. 3A and 3B are high magnification HAADF-STEM images of a quasi-two-dimensional metal nanosheet according to an embodiment of the present invention;

FIG. 4 is a representative TEM image of Turing stripes distribution of a quasi-two-dimensional metal nanosheet according to an embodiment of the present invention;

FIG. 5 is a SAED pattern taken from FIG. 3B indexed with the face-centered cubic structure of a quasi-two-dimensional metal nanosheet an embodiment of the present invention;

FIG. 6 is a STEM-EDS line-scanning analysis on a Turing stripe of a quasi-two-dimensional metal nanosheet according to an embodiment of the present invention;

FIG. 7 is an atomic resolution HAADF-STEM image of a five-fold-twined junction in Turing stripe of a quasi-two-dimensional metal nanosheet according to an embodiment of the present invention;

FIG. 8 shows the fast Fourier transform patterns of grains marked in the five-fold twins in FIG. 7;

FIG. 9 is an atom arrangement in the junction of Turing stripe of a quasi-two-dimensional metal nanosheet according to an embodiment of the present invention;

FIGS. 10A and 10B show the theoretical angles of the face-centered cubic structure of FIG. 9;

FIG. 11 is a strain mapping for the area of the five-fold twined node shown in FIG. 9;

FIG. 12 is a constituent grain on the Turing stripe, and the insertion shows schematic atom arrangement of the strain mapping around a stacking fault;

FIG. 13 is a diagram showing a Turing stripe formed by end-to-end joined single-grain along similar axial direction;

FIG. 14 is a linear sweep voltammetry curves of different samples in 1.0 M KOH;

FIG. 15 shows the overpotential at 10 mA cm⁻² and mass activity at 100 mV of samples in FIG. 14;

FIG. 16 shows tafel slopes of the Turing PtNiNb, monometallic Pt 2D metal, and commercially available Pt/C;

FIG. 17 shows C_{dl} value of Turing PtNiNb and Pt 2D metal;

FIGS. 18A-18C show the results of Cu_{upd} stripping experiments and TOF of Turing PtNiNb;

FIG. 19 shows the turnover frequency value of Turing PtNi compared with other recently reported HER electrocatalysts in alkaline electrolyte;

FIG. 20 shows the results of long-period durability test at a constant current density of 100 mA cm⁻²;

FIG. 21 shows long-time stability test under large-current-density in 1.0 M KOH for Turing PtNi, and the insertion shows HAADF-STEM image after 60 hours measurement and LSV curves comparison before and after the measurement;

FIG. 22 shows potentiostatic measurement continuing 24 hours at applied potential of −1.1221V for Turing PtNi;

FIG. 23 shows variation of current density during accelerated durability test of the samples in FIG. 14;

FIG. 24 shows the XPS analysis results of Turing PtNi; and

FIG. 25 shows mass hydrogen production in stability test and overpotential of the samples in FIG. 13 in comparison with reported HER electrocatalysts.

### DETAILED DESCRIPTION

In order to make the aforementioned objects, features and advantages of the present invention comprehensible, embodiments accompanied with figures are described in detail below.

In the following description, numerous specific details are set forth in order to provide a thorough understanding of the present invention, but the present invention may be practiced in other ways than those specifically described and will be readily apparent to those of ordinary skill in the art without departing from the spirit of the present invention, and therefore the present invention is not limited to the specific embodiments disclosed below.

Bottom-up construction is a widely used method to synthesize low-dimensional nanoscale electrocatalyst, for example, nanocage and 2D metallene, in which the structures with broken crystallographic symmetry are produced under a diffusion dominated non-equilibrium conditions and kinetic process. In biological and chemical systems, severely disrupted equilibrium gives rise to periodic, spatiotemporal stationary patterns, which is called Turing pattern. Turing patterns is usually found in ‘soft’ organic matter and limited inorganic substances. Turing pattern is characterized by zebrafish stripes, patterns resembling sea-shells and hexagonal arrays in a microemulsion.

As an indication of a steady state, Turing structure originates from energy dissipation of the entire non-equilibrium system. The mechanism underlying stationary biological/chemical patterns was first elucidated by Alan Turing based on reaction-diffusion theory. Later, Turing structure evolved as an important structure motif to tune property and trace mechanism in biology and chemistry at the scale from centimeter to micrometer. More recently, the discovery of Turing-patterned bismuth monolayer provides strong support that Turing morphogenesis is a likely occurrence in nanoscale inorganic crystal lattice. These findings indicate that a new morphology can be defined: two-dimensional (2D) metals with Turing structure. Due to morphogenesis-introduced high-density twins and inhomogeneously distributed strain, Turing structure is a new paradigm for design of low-dimensional nano-catalysts and opens a way to integrate defect modulation and strain effects to optimize catalytic reactivity and durability. Such 2D metals with Turing structure can be finely tuned, including degree of freedom, lattice strain, and defects, to be a malleable model for an electrocatalyst with high durability.

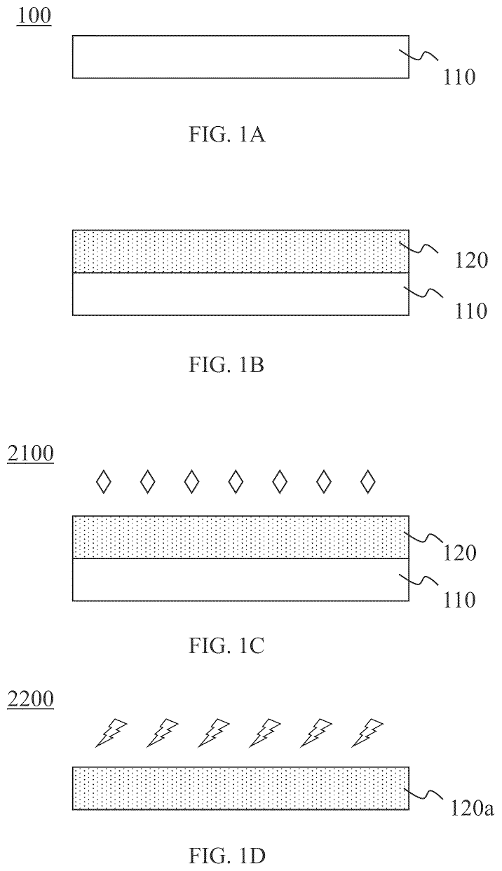

A method 100 of manufacturing an electrocatalyst is provided. Turning to FIG. 1A, a buffer layer 110 is formed by sputtering. The buffer layer 110 is made from SiO₂, ZnO₂, Cr₂O₃, tin (Sn), aluminum (Al), lead (Pb), or a combination thereof. Next, turning to FIG. 1B, a metal layer 120 is formed on the buffer layer 110. The metal layer 120 is formed by sputtering. The metal layer 120 includes platinum (Pt), nickel (Ni), and niobium (Nb). The Pt is in a range between 10 and 75%, Ni is in a range between 20 and 60%, and Nb is in a range between 5 and 30%. In one embodiment, the metal layer 120 is composed of 50% of Pt, 35% of Ni and 15% of Nb. In another embodiment, the metal layer 120 is composed of 60% of, 30% of Ni and 10% of Nb. The sputtering of the buffer layer 110 and the metal layer 120 can be magnetron sputtering or co-sputtering of two to four targets. Turning to FIG. 1C, subsequently, the buffer layer 110 and metal layer 120 undergo exfoliation 2100 in an alkaline solution. The alkaline solution includes, for example, 1 M KOH and 1 M NaOH. In the exfoliation 2100, a temperature ranging between 300 and 370K is applied. In one embodiment, the temperature ranges between 313 and 368K in the exfoliation 2100.

Turning to FIG. 1D, after exfoliation, the buffer layer 110 is substantially removed from the metal layer 120a. The metal layer 120a then undergoes at least one cycle of ultrasonic treatment 2200. A duration of the ultrasonic treatment 2200 ranges between 10 and 100 minutes. A temperature applied in the ultrasonic treatment 2200 ranges between 270 and 300K. In one embodiment, the ultrasonic treatment is conducted in two cycles, and the duration and temperature in each cycle are different from each other. In one embodiment, a first ultrasonic treatment is performed at a temperature at 298K for a duration between 10 and 90 minutes. A second ultrasonic treatment is performed at a temperature at 273K for a duration between 30 and 90 minutes. It should be understood that different combinations of the temperature and duration in each cycle is permissible, given the temperature and duration fall within the predetermined range. After the ultrasonic treatment, a quasi-two-dimensional metal nanosheet is completed. The thickness of the quasi-two-dimensional metal nanosheet can be tuned to a range between 1 and 100 nm. In one embodiment, the quasi-two-dimensional metal nanosheet has a thickness ranging between 4 and 12 nm. The quasi-two-dimensional metal nanosheet has a length/width ranging between 50 and 2000 nm. In one embodiment, the quasi-two-dimensional metal nanosheet has a length/width ranging between 100 and 500 nm.

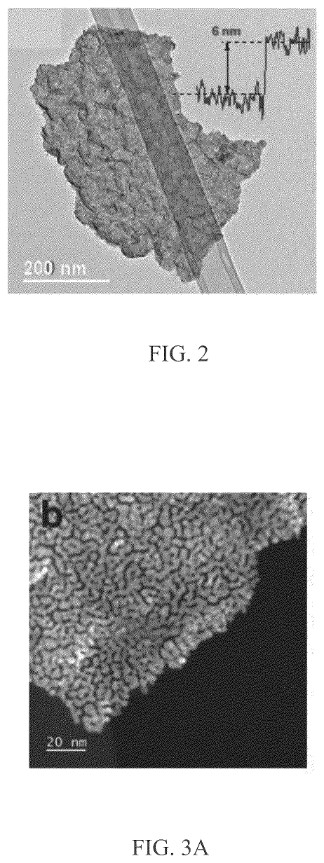

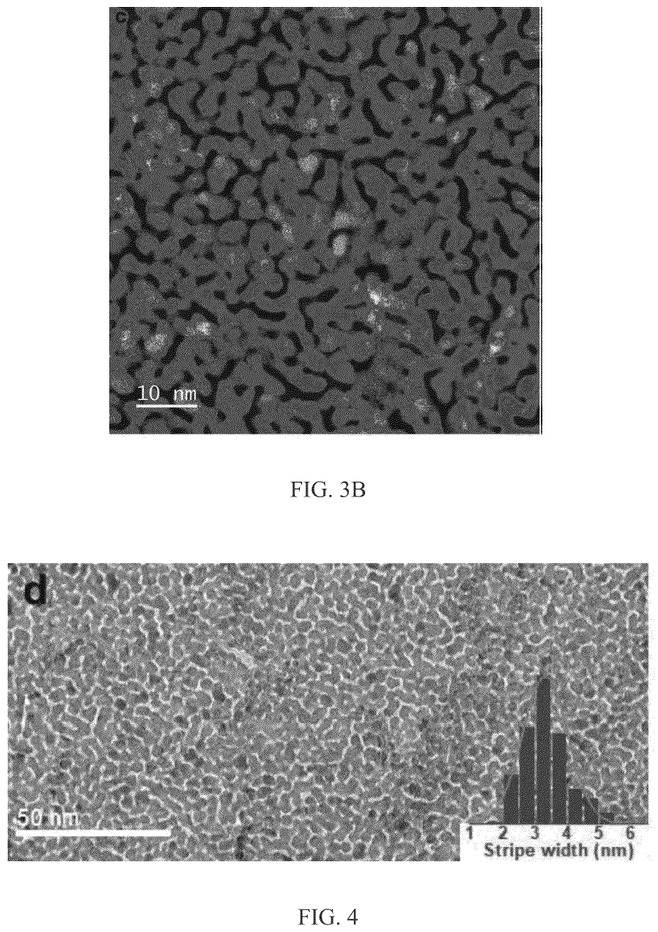

Turning to FIG. 2, a low magnification TEM image of a quasi-two-dimensional metal nanosheet according to an embodiment of the present invention is shown. In FIG. 2, the free-standing quasi-two-dimensional metal nanosheet having PtNiNb is semitransparent and locally wrinkled. These features suggest that the quasi-two-dimensional metal nanosheet is highly flexible. The thickness of the quasi-two-dimensional metal nanosheet, which ranges between 1 and 100 nm, is thinner and more refined than conventional 2D metals synthesized by organic ligand-confined growth and bulk-exfoliation. Turning to FIGS. 3A and 3B, high magnification HAADF-S TEM images of a quasi-two-dimensional metal nanosheet according to an embodiment of the present invention are shown. The isolated nano-grains joint locally and form the nanoscale Turing stripes. Turning to FIG. 4, a representative TEM image of Turing stripes distribution of a quasi-two-dimensional metal nanosheet according to an embodiment of the present invention is shown. The Turing stripes are evenly distributed in the structure of the quasi-two-dimensional metal nanosheet. The insertion shows the size distribution of Turing stripe. The size of the Turing stripe is determined by width or diameter of the constituent nano-grains. The Turing stripe has a majority of stripe width measuring approximately between 2.5 and 4 nm.

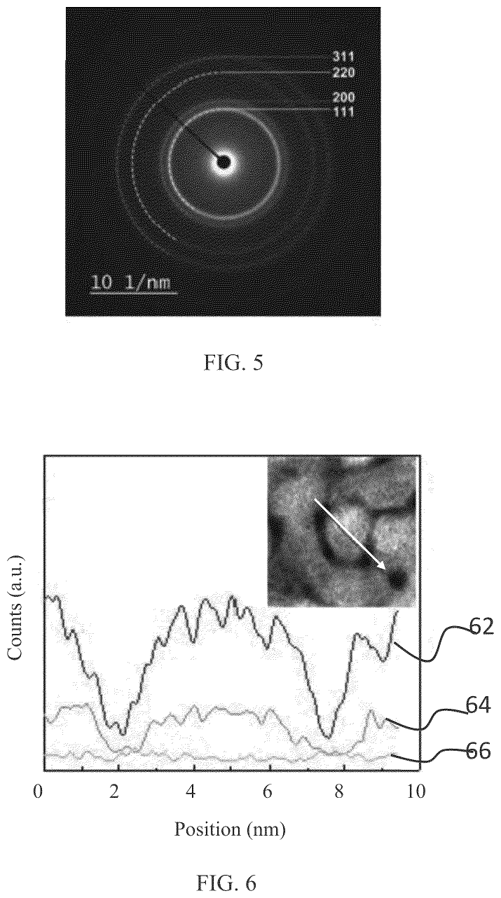

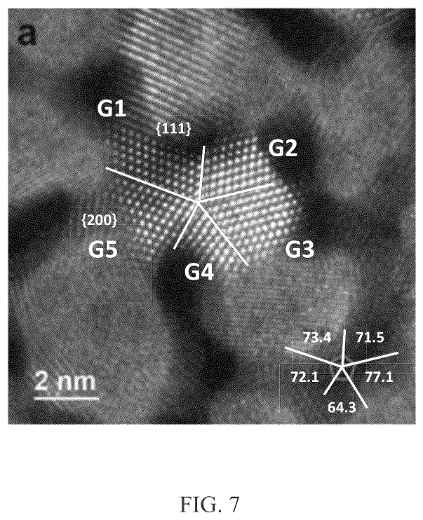

Turing to FIG. 5, a SAED pattern taken from FIG. 3B indexed with the face-centered cubic (fcc) structure of a quasi-two-dimensional metal nanosheet an embodiment of the present invention is shown. An fcc structure has four atoms in each unit cell. These four atoms are the collective number from the eight corner atoms (one eighth) and six face atoms (one half) arranged in a cube of a unit cell. A coordination number (i.e., the number of nearest neighbors that each atom has) of an atom in the fcc structure is 12. This is a stable and tightly packed atomic arrangement. In FIG. 5, the number 111 indicates crystal facet set of {111}, number 200 indicates crystal facet set of {200}, number 220 indicates crystal facet set of {220}, and number 311 indicates crystal facet set of {311}. Turning to FIG. 6, a STEM-EDS line-scanning analysis on a Turing stripe of a quasi-two-dimensional metal nanosheet according to an embodiment of the present invention is shown. The x-axis shows the position marked by nm, and the y-axis shows the counts in arbitrary unit. The insertion in FIG. 6 is the analyzed strip-constituted nano-grain of the quasi-two-dimensional metal nanosheet. The arrow represents the line-scanning direction for the STEM-EDS analysis. Line 62 indicates Pt intensities at different positions, line 64 indicates Ni intensities at different positions, and line 66 indicates Nb intensities at different positions.

High resolution lattice images are obtained for detailed crystallographic characters of the quasi-two-dimensional metal nanosheet. Twins and crystalline defects (stacking fault and lattice distortion) are observed in the nano-grains of the quasi-two-dimensional metal nanosheet. The term “twin” refers to a pair of grains that are substantially identical except their orientations in space. More specifically, a twin is a pair of grains that reflects one another substantially the same across a common plane. In a quasi-two-dimensional metal nanosheet, five-fold twins and two-folds twins have high occurrence. The frequency ratio of five-fold twins, two-fold twins and one-fold twins is approximately 55%:18%:27%.

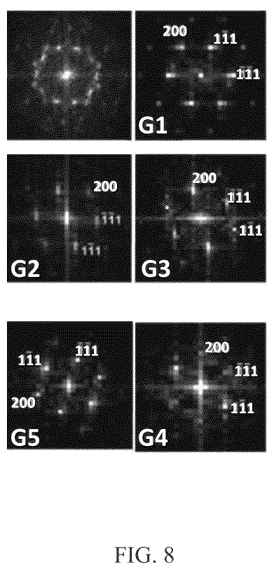

Turning to FIGS. 7 and 8, an atomic resolution HAADF-STEM image of a five-fold-twined junction in Turing stripe of a quasi-two-dimensional metal nanosheet according to an embodiment of the present invention and the fast Fourier transform (FFT) patterns of nano-grains marked in the five-fold twins in FIG. 7 are shown respectively. G1 to G5 in FIGS. 7 and 8 indicate the nano-grains in the five-fold twins. The five-fold twins joint the neighboring nano-grains at different orientations. The solid white lines indicate the coherent twin boundaries where the neighboring nano-grains meet. The angles for G1 to G5 are 73.4°, 71.5°, 77.1°, 64.3° and 72.1° in order. Many branched junctions are made up of individual five-fold twins and enclosed by {111} and {200} atomic planes. As shown in FIG. 8, the FFT patterns of the diffraction spots of {111} and {200} planes from the five nano-grains are visualized alone [110] zone axis. The atom arrangement on both sides of {111} twin boundary is substantially symmetric with the stacking sequence of ABC|CBA. In short, the twin boundary of the Turing junction with five-fold twins is a {111} coherent twin boundary (Σ3{111} TB). Twin boundary (TB) is the interface between two separate crystals that are mirror images of each other, and it stands for tangents to a circle with center O from an external point T.

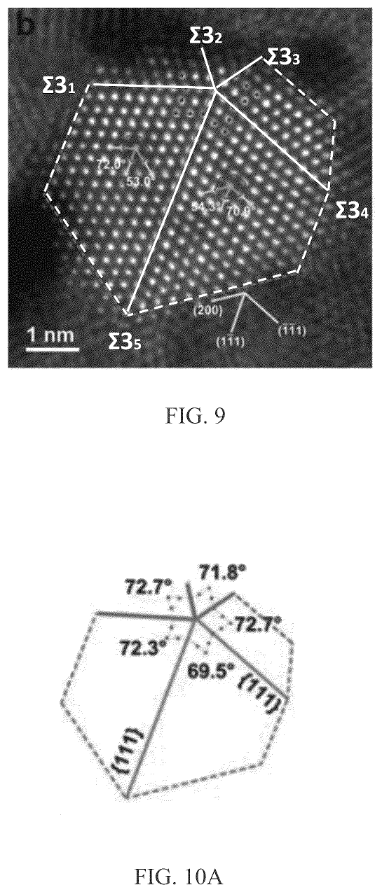

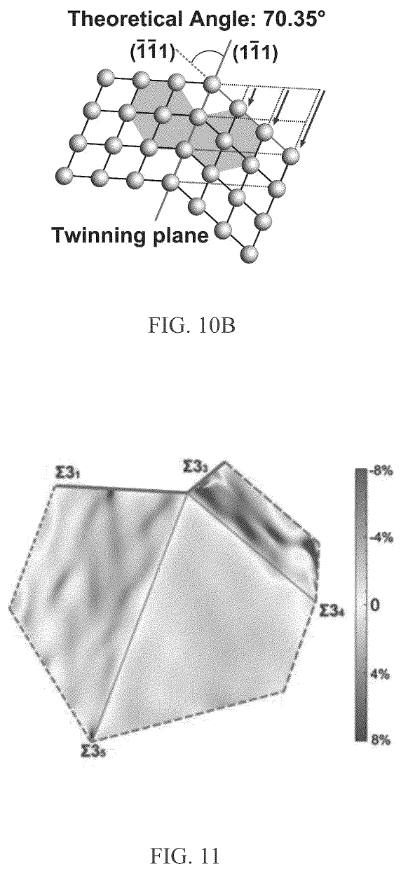

Turning to FIGS. 9 and 10, an atom arrangement in the junction of Turing stripe of a quasi-two-dimensional metal nanosheet according to an embodiment of the present invention and their empirical and theoretical angels are shown respectively. In an fcc structure, the theoretical angle between {111} planes (Turing planes) is 70.35° shown in the bottom panel in FIG. 10. In theory, a space-filling of a five-fold symmetrical configuration requires a compensation misfit angle of 7.35°. In a conventional fcc structure at a nano-scale, the misfit angle (7.35°) is compensated by inserting a wedge disclination along [110] direction for {111} twin boundaries. However, in the five-fold twins in a Turing structure, wedge disclination is not observed. Turning to FIG. 9, the white solid lines denote the Σ3{111} TB twin boundaries (junctions of Turing stripe) in the five-fold twins of a quasi-two-dimensional metal nanosheet. Turning to the top panel in FIG. 10, the angles between the Σ3{111} TB twin boundaries between (1̅1̅1) and (11̅1) of the fcc structure shown in FIG. 9 are simplified and labelled. The quasi-two-dimensional metal nanosheet have angles between Σ3{111} TB twin boundaries of 72.7°, 71.8°, 72.7°, 69.5°, and 72.3° respectively. The angles between the Σ3{111} TB twin boundaries deviate from the theoretical value (70.35°). These inhomogeneous angles between the Σ3{111} TB twin boundaries suggest a heterogeneous distribution of wedge disclination between the neighboring twins in the quasi-two-dimensional metal nanosheet. This atomic structure will lead to larger lattice strain because the elastic energy has to be accommodated.

Geometric phase analysis is used to quantitatively describe the lattice strain distribution of Turing structure in the quasi-two-dimensional metal nanosheet. Strain mapping gives information about the heterogeneous distribution of lattice strain in relation to the Σ3{111} TB twin boundaries. Turning to FIG. 11, a large portion of twin pair between the Σ3₃-Σ3₄ is expanded with tensile strain, and the average lattice strain is approximately 4.3%. The average tensile strain between Σ3₁-Σ3₅ is approximately 3.1%. The average tensile strain between Σ3₄-Σ3₅ is approximately 2.6%. The lattice strain of the five-fold twins is not distributed evenly. Higher lattice strain tends to sustain at the edges and the Σ3{111} TB twin boundaries. The lattice strain is less intense at the dipole of the five-fold twins.

This lattice strain distribution of the five-fold twins in Turing structure is different from the five-fold twins which has a free boundary. More specifically, the five-fold twins which have a free boundary have unconfined nanoparticles. In other words, crystals rotate randomly according to accommodation of orientation attachment. The maximum lattice strain of the five-fold twins which have a free boundary appears at dipoles of such twins. This pattern of lattice strain at dipoles is likely the result of wedge disclination, which is induced by elastic energy, attenuating with increased radius. The heterogeneous distribution of lattice strain in the five-fold twins which has a free boundary suggests that five-fold twins are a crystallographic protocol to accommodate orientation misfit among the grains at the twin boundaries. However, even though the five-fold twins relieve orientation misfit, the existing crystals cannot be fully reconstructed according to orientation accommodation. On the other hand, a heterogeneous lattice strain distribution in the five-fold twins in a Turing structure can fully accommodate the elastic energy, and hence the absence of wedge disclination.

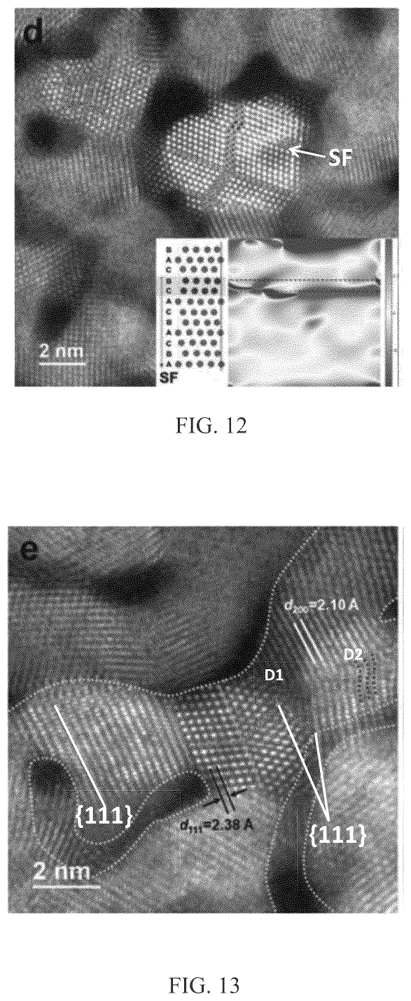

In addition to the five-fold twins, orientation misfit accommodation in the Turing structure can be achieved by twining-twining, meaning two pairs of twins with parallel twin boundaries in a nanograin, and twining-stacking fault along the same direction. Turning to FIG. 12, a constituent grain on the Turing stripe and the insertion showing schematic atom arrangement of the strain mapping around a stacking fault (SF) are shown. Residual lattice misfit and the lattice distortion originated from staking fault induce large lattice strain in the nano-grains cut through by twins and stacking fault. The formation of the Turing structure can accommodate constrained orientation attachment. In other words, the formation of the Turing structure is based on the constrained orientation attachment of nanograins.

Turning to FIG. 13, a diagram of a Turing stripe formed by end-to-end jointed single-grain along a substantially identical axial direction is shown. The stripe formation is achieved by accommodation, in a rotation or torsion manner, of nanocrystals, twins and lattice distortions. A Turing stripe includes a rotational crystal, which rotates along <111>, twins, deflecting crystals and local regions with large lattice distortions D1 and D2, as shown in FIG. 13. D1 is a local band of lattice distortion that spans across the nano-grain from one end to another. D2 is a local patch of lattice distortion that is contained in a small area. And by measuring the intensity profiles along {111} and {200} facets, it indicates that the sizes of the crystal lattice thereof are 2.38 Å and 2.10 Å respectively. In the quasi-two-dimensional metal nanosheet having Turing PtNiNb arranged in Turing morphology, densely packed five-fold twins and large lattice strain from its crystalline structure are important for its electrical characters, durability and compact dimension.

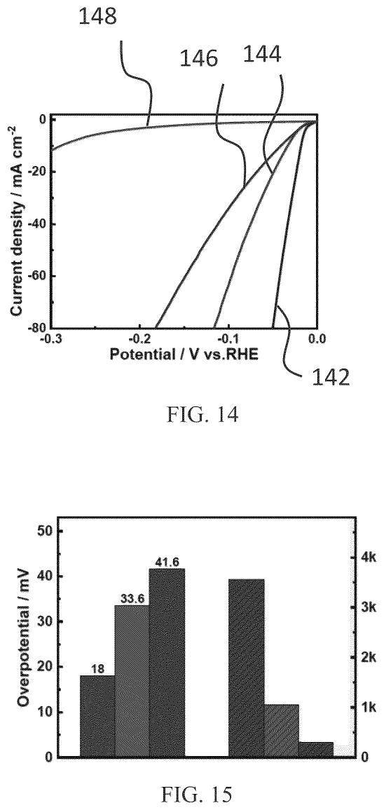

The quasi-two-dimensional metal nanosheet having PtNiNb arranged in Turing morphology exhibits stability in hydrogen evolution reaction (HER) in alkaline electrolyte. The twins and lattice distortion provide a strong catalytic activity. Turning to FIG. 14 in conjunction with FIG. 15, the graphs show linear sweep voltammetry (LSV) curves of different samples in 1.0 M KOH and the overpotential at 10 mA cm⁻² and mass activity at 100 mV of these samples. Curve 142 is the readout from a sample of Turing PtNiNb, curve 144 is a monometallic Pt 2D metal, curve 146 is a commercially available Pt/C, and curve 148 is an amorphous NiNb quasi-two-dimensional metal. The Turing PtNiNb, curve 142, has the lowest overpotential which is about η₁₀ of approximately 18 mV in HER in comparison with the other samples. The monometallic Pt 2D metal has η₁₀ of approximately 33.6 mV, and the commercially available Pt/C has η₁₀ of approximately 41.6 mV.

Turning to FIG. 15 again, the mass activity of Turing PtNiNb reaches 3570.8 mAmg⁻¹ₚₜ. The commercially available Pt/C has a mass activity of 310.5 mAmg⁻¹ₚₜ, and the monometallic Pt 2D metal has a mass activity of approximately 1050.0 mAmg⁻¹ₚₜ. The Turing PtNiNb shows nearly 11.5 times higher mass activity than the commercially available Pt/C and 3.4 times higher than the monometallic Pt 2D metal.

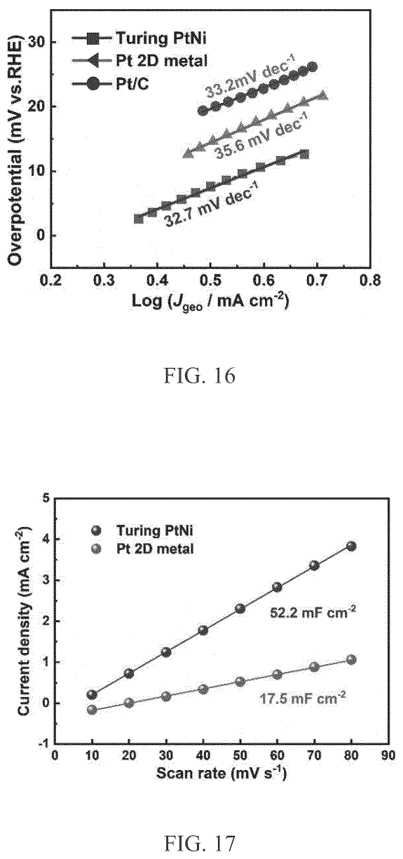

As shown in FIG. 16, tafel slopes of the Turing PtNiNb, monometallic Pt 2D metal, and commercially available Pt/C are close to 29.mV dec⁻¹. It should be understood that the Tafel step (2 M-H* [symbol] H₂+2 M) is the rate-determining step in the process of HER. Volmer-Tafel mechanism is one of reaction mechanisms in the hydrogen evolution reaction. In the alkaline media, hydrogen atoms are absorbed electrochemically on the catalytic surface of materials in Volmer step and one proton captures one electron during this process; then Tafel reaction enables 2 near-formed H* to bind together subsequently H₂ is formed.

The intrinsic activity of Turing PtNiNb is further assessed by calculating its double-layer capacitance (C_{dl}) and turnover frequency (TOF). As shown in FIG. 17, Turning PtNi has a higher C_{dl} value than Pt 2D metal. The calculated results reflect quantity and ability to generate H₂ by Turing PtNiNb at its active sites. High C_{dl} value of approximately 52.2 mF cm⁻² is observed in Turing PtNiNb. The monometallic Pt 2D metal has a C_{dl} value of approximately 17.5 mF cm⁻². Turing PtNiNb has a C_{dl} value that is about three times higher than the monometallic Pt 2D metal. It suggests that Turing PtNiNb has about three times more active sites than the monometallic Pt 2D metal.

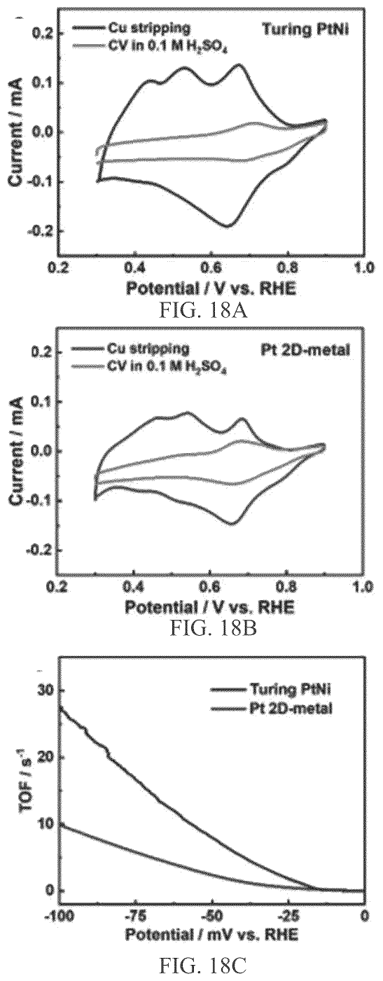

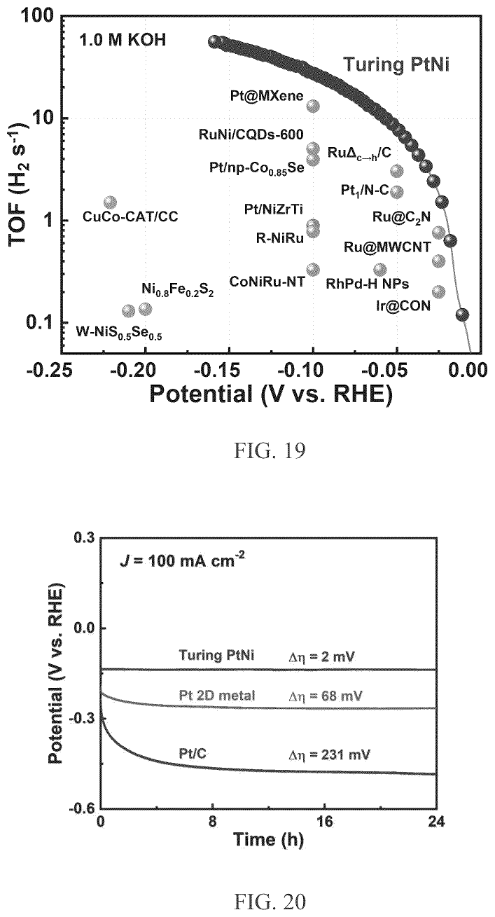

Turning to FIGS. 18A-18C, based on electrochemically specific surface area (ECSA) derived from the Cu_{upd} stripping experiments (FIGS. 18A-18B), TOF of Turing PtNiNb is quantified to be 27.5H₂ s⁻¹ at the overpotential of 100 mV (FIG. 18C). Referring to FIG. 19, the TOF of the previously reported electrocatalysts for HER in alkaline solution is less than 27.5H₂ s⁻¹ under the same condition. The TOF value of the other reported electrocatalysts is listed in Table 1.

TABLE 1

| Catalyst | Overpotential (V) | TOF (S⁻¹) |
|---|---|---|
| PT@MXene | 0.1 | 13.08 |
| Pt₁/N—C | 0.05 | 1.89 |
| Pt/np-Co_{0.85}Se | 0.1 | 3.93 |
| Pt/NiZrTi | 0.1 | 0.89 |
| CoNiRu-NT | 0.1 | 0.33 |
| Ru@MWCNT | 0.025 | 0.4 |
| Ir@CON | 0.025 | 0.2 |
| Ru@C2N | 0.025 | 0.76 |
| RhPd—H NPs | 0.06 | 0.33 |
| Ru/Δ_{c→h}C | 0.05 | 3.03 |
| R-NiRu | 0.1 | 0.78 |
| RuNi/CQDs-600 | 0.1 | 5.03 |
| W—NiS_{0.5}Se_{0.5} | 0.21 | 0.13 |
| CuCo-CAT/CC | 0.221 | 1.5 |
| Ni_{0.8} Fe_{0.2}S₂ | 0.2 | 0.2 |

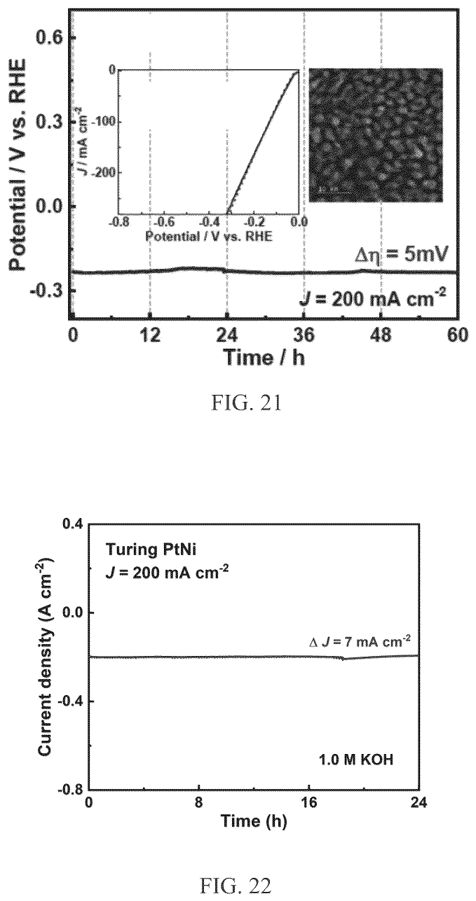

The Turing structure also contributes to the stability of the Turing PtNiNb quasi-two-dimensional metal nanosheet in alkaline HER. Referring to FIG. 20, Turing PtNiNb has the highest stability with a slight overpotential change of 2 mV in a long-period durability test at a constant current density of 100 mA cm⁻². The result shows a higher degree of durability in comparison with the control samples. The overpotential of Pt 2D metal changes 68 mV and that of Pt/C changes 231 mV in the long-period durability test at a constant current density of 100 mA cm⁻². Turning to FIG. 21, Turing PtNiNb maintains a large current density of 200 mA cm⁻² with a negligible potential difference in the duration of 60 hours in 1.0 M KOH. The insertions in FIG. 21 show an HAADF-STEM image of the Turing PtNiNb and LSV curves of the Turing PtNiNb prior and after the 60-hour test. The HAADF-STEM image suggests the invariability in the Turing structure, and the XPS (X-ray photoelectron spectroscopy) results provides information about the element valences of the Turing PtNiNb. According to the results of the LSV curves, Turing PtNiNb has a stable and substantially identical LSV curves prior and after the 60-hour durability test.

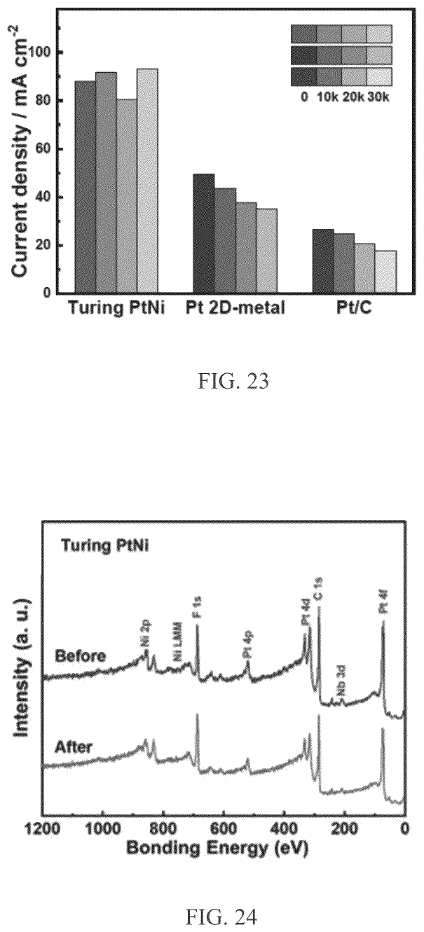

Turning to FIG. 22, the potentiostatic measurement at −1.221 V (vs. Hg/HgO) and accelerated durability test (ADT) demonstrate the stability of Turing PtNiNb. In FIG. 22, the samples undergo multiple CV cycles from 0 to 30,000 cycles between 0 to −0.2 V. Comparing the current density at 60 mV, The Turing PtNiNb maintains its current density at about 80 to 90 mA cm⁻², and there is no decrement after 30 k CV cycles. The monometallic Pt 2D metal and the commercially available Pt/C show much lower current density at the beginning and discernable decay as the number of CV cycles goes up. The results suggest that Turing PtNiNb quasi-two-dimensional metal nanosheet has high stability and is suitable for mass hydrogen production and application in industrial anion-exchange membrane (AEM) electrolyzer. The Turing PtNiNb loaded on the carbon paper as anode catalyst is assembled into the AEM electrolyzer and assist the hydrogen generation. Turning to FIG. 23, samples including Turing PtNiNb, monometallic Pt 2D metal, commercially available Pt/C, Pt based metal, PtNi based metal, and other platinum-group-metal (PGM) based metal are tested for mass hydrogen production in alkaline electrolyte. The Turing PtNiNb has a high mass H₂ production of 53.04 C g⁻¹_{PGM} and a low overpotential at 10 mA cm⁻² of 18 mV. The other samples, for example, the monometallic Pt 2D metal has a mass H₂ production of approximately 10 C g⁻¹_{PGM} and an overpotential at 10 mA cm⁻² of 35 mV. The other PGM based catalysts have mass H₂ production of approximately 1 C g⁻¹_{PGM} and an overpotential at 10 mA cm⁻² over 18 mV. None of the tested samples has both high mass H₂ production rate and low overpotential as the Turing PtNiNb. In other words, the Turing PtNiNb has the best performance among the test samples.

The atomic arrangement of the Turing PtNiNb contributes to its stable performance in alkaline HER. As to the activity, the quasi-two-dimensional architecture enlarges the electrochemical specific area and exposes large interfaces (active sites) for efficient reaction, thus enhancing catalytic activity. The twins, stacking faults and lattice distortion of the Turing PtNiNb introduce lattice strain that modulates the surface electron distribution which balances the bonding energy between the active sites and intermediates. This adjustment on the surface electron distribution creates a suitable interaction force between the reactive components and facilitate adsorption/desorption in the process. Consequently, the active sites can quickly release the intermediates and return for a new cycle of HER because the molecular interaction force is moderate.

Moreover, synergistic effect in Turing PtNiNb facilitates HER. More specifically, Ni-active sites (mainly Ni(OH)2) enables water molecules to release H as the input for H₂ generation in alkaline electrolyte, and Ni atoms modify their surrounding Pt electronically. Meanwhile, Pt-active sites act as M-H bonding sites in the Volmer-Tafel mechanism. Referring to FIG. 24, according to the XPS analysis, the Nb peaks shift to a higher bonding energy area compared with the standard range of Nb peak position of 201.5-202.8 eV (Nb(0) 3d5/2). This bonding energy shift suggests the electron transfer from Nb to Pt and Ni to facilitate the catalytic activity.

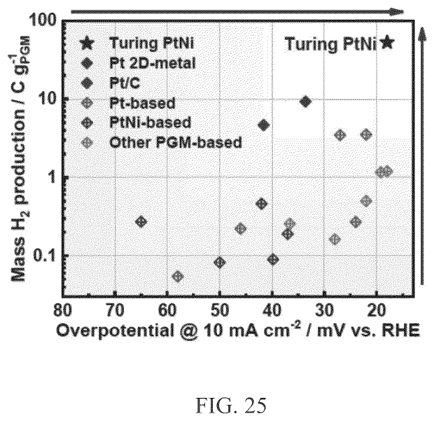

The Turing PtNiNb has nano-grains that joint into a large sheet. This nano-grain arrangement provides high durability and prevents aggregation. As shown in FIG. 25, the end-to-end jointed single grains form nodes at the junction that minimizes deformation in alkaline HER. These structural merits ensure the stability and productivity of the Turing PtNiNb in the prolonged catalytic process. The balanced bonding energy prevents the active sites being occupied by the intermediates. The quick release of intermediates by the active sites lead to a fast turn-over rate of the catalyst even under long period of time. The quasi-two-dimensional metal nanosheet having a Turing structure morphology, including Turing stripes, spots, twins, stacking faults, lattice distortion, and lattice strain, is stable and durable and has high mass H₂ production rate in alkaline HER.

As used herein, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the present disclosure include endpoints. The term “substantially coplanar” may refer to two surfaces within a few micrometers (μm) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

1. An electrocatalyst comprising
a quasi-two-dimensional metal nanosheet having a thickness ranging between 4 nm and 12 nm;
the quasi-two-dimensional metal nanosheet including platinum (Pt), nickel (Ni), and niobium (Nb);
the quasi-two-dimensional metal nanosheet having a Turing structure morphology including one or more of Turing stripes and Turing spots assembled by individual metal nanocrystals having different orientations via constrained orientation attachment.

2. The electrocatalyst of claim 1, wherein the Pt is in a range between 10 and 75%, Ni is in a range between 20 and 60%, and Nb is in a range between 5 and 30%.

3. The electrocatalyst of claim 1, wherein the quasi-two-dimensional metal nanosheet has a face-centered cubic (fcc) structure.

4. The electrocatalyst of claim 1, wherein the Turing structure morphology includes five-fold twins enclosed by {111} and {200} atomic planes.

5. The electrocatalyst of claim 1, wherein a lattice strain of the quasi-two-dimensional metal nanosheet is in a range between 2.5 and 4.3%.

6. The electrocatalyst of claim 1, wherein the Turing stripes are rotational crystals.

7. A method of manufacturing the quasi-two-dimensional metal nanosheet catalyst of claim 1, comprising:
forming a buffer layer by sputtering;
forming a metal layer having platinum (Pt), nickel (Ni), and niobium (Nb) over the buffer layer by sputtering;
exfoliating the buffer layer and the metal layer in an alkaline solution; and
performing ultrasonic treatment to the buffer layer and the metal layer for at least one cycle.

8. The method of claim 7, wherein the forming the buffer layer by sputtering and forming the metal layer over the buffer layer is magnetron sputtering.

9. The method of claim 7, wherein the buffer layer is selected from the group consisting of SiO₂, ZnO₂, Cr₂O₃, tin (Sn), aluminum (Al), and lead (Pb).

10. The method of claim 7, wherein the Pt is in a range between 10 and 75%, Ni is in a range between 20 and 60%, and Nb is in a range between 5 and 30%.

11. The method of claim 7, wherein the exfoliating the buffer layer and the metal layer in the alkaline solution is performed at a temperature ranging between 310 and 370K.

12. The method of claim 7, wherein the performing ultrasonic treatment to the buffer layer and the metal layer for at least one cycle is conducted at a temperature ranging between 270 and 300K.

13. The method of claim 12, wherein the performing ultrasonic treatment to the buffer layer and the metal layer has two cycles, and each cycle has a different temperature.
